(19) United States
(12) Patent Application Publication
(10) Pub. No.: US 2024/0164075 A1
(43) Pub. Date: May 16, 2024

(54) A Housing for Optical Transceivers

(71) Applicant: Telefonaktiebolaget LM Ericsson (publ), Stockholm (SE)

(72) Inventors: Claudio D'Incà, Genova (IT); Alberto Deho, Genova (IT); Sergio Mosti, Genova (IT)

(21) Appl. No.: 18/551,051

(22) PCT Filed: Mar. 22, 2021
(86) PCT No.: PCT/EP2021/057271

§ 371 Date: Sep. 18, 2023

(51) Int. Cl. H05K 9/00; H04B 10/40

(52) U.S. Cl. CPC H05K 9/0058; H05K 9/002; H04B 10/40

(57) ABSTRACT

A housing for optical transceivers is provided. The housing comprises a plurality of walls defining a plurality of spaces for receiving optical transceivers, e.g. pluggable optical transceivers. The housing defines a plurality of openings into the respective spaces. The housing further comprises a cover movably coupled to one of the walls, the cover movable relative to the one of the walls in order to cover one of the openings, when the space corresponding to the opening is vacant.

### TECHNICAL FIELD

The present disclosure relates to a housing for optical transceivers and is particularly, although not exclusively, concerned with a housing for optical transceivers which improves electromagnetic shielding of the housing when one or more spaces of the housing for receiving the optical transceivers are vacant.

### BACKGROUND

Telecommunications units may be equipped with a plurality of electrical components, such as optical transceivers, e.g. Small Form-factor Pluggable (SFP) optical transceivers, and/or plugs for Direct-Attached Copper (DAC) cable assemblies, which are installed into the units. The electrical components may be for facilitating data communications between the telecommunications units. When designing the telecommunications units for housing such electrical components, it is desirable to ensure that the units operate within proscribed limits of electromagnetic interference emission, e.g. by preventing undesirable levels of electromagnetic interference generated by the electrical component being emitted from the unit. Ensuring that the electrical components are suitably shielded may be of particular importance when the telecommunications unit is configured to house multiple electrical components, such as optical transceivers, each of which may generate electromagnetic interference.

With reference to FIGS. 1 and 2, the telecommunications units may comprise a dedicated housing 100 or cage provided as part of the telecommunications unit for housing the electrical components. As depicted, the housing 100 may comprise a plurality of walls 102 defining a plurality of spaces 104 for receiving electrical components, such as SFP optical transceivers and/or plugs of DAC cable assemblies, within the housing 100. Each of the spaces 104 may be configured to receive an optical transceiver, plug for a DAC cable assembly or another electrical component. The housing 100 may define openings 106 into the respective spaces for the electrical components to be installed through into the spaces 104.

The housing 100 may serve the purpose of aligning the SFP optical transceivers or DAC cable assembly plugs with respective electrical connectors 112, e.g. provided on a printed circuit board 110 of the telecommunications unit. The electrical connector 112 may be, for example, for supplying power and/or transmitting control/data signals to the optical transceiver and/or DAC cable assembly plug.

The housing 100 also has the purpose of ensuring that an appropriate ground connection is established between the housing 100 and a frame (not shown) of the telecommunications unit. As shown in FIG. 1, the housing 100 comprises a plurality of sprung fingers 108 for contacting the frame of the telecommunications unit in which the housing 100 is installed. For example, the sprung fingers 108 may be to contact a front panel of the frame to establish the ground connection. Ensuring the appropriate ground connection between the housing 100 and the telecommunications unit, may enable the electrical components, e.g. the optical transceivers and/or DAC cable assembly plugs, to be electromagnetically insulated within the telecommunications unit, as described below.

With reference to FIG. 3, the electrical components 300 may comprise a casing 302 and a plurality of electrical contacts 304 for contacting the housing 100 in order to establish a reliable ground connection between the casing 302 and the housing 100. The electrical contacts 304 may be sized and spaced apart over the casing 302, such that when the optical transceiver 300 is installed within the housing, gaps present between ground connections between the casing 302 and the housing 100 are sufficiently small to appropriately attenuate electromagnetic interference generated by the electrical component 300. In this way, any electromagnetic interference generated by the electrical component may be appropriately attenuated before being emitted from the telecommunications unit.

However, as illustrated in FIG. 4, when one or more of the spaces 104 defined by the housing 100 for receiving the electrical components are vacant, i.e. an electrical component is not installed within the space, the openings 106 into the vacant spaces may enable electromagnetic interference being generated by electrical components installed in other spaces of the housing 100 to be emitted from the housing without being adequately attenuated. In order to improve the attenuation of electromagnetic interference in such situations, one or more insulating plugs may be installed in the openings 106 into the vacant spaces, which act to reduce the emission of electromagnetic interference through these openings.

The use of such insulating plugs for reducing the emission of electromagnetic interference from telecommunications units may rely on an installer or technician installing the appropriate insulating plugs into the appropriate openings, in order to achieve a desirable level of electromagnetic interference shielding.

### SUMMARY

According to an aspect of the present disclosure, there is provided a housing comprising a plurality of walls defining a plurality of spaces for receiving optical transceivers, e.g. pluggable optical transceivers. The housing defines a plurality of openings into the respective spaces. The housing comprises a cover movably coupled to one of the walls, the cover movable relative to the one of the walls in order to cover at least one of the openings, e.g. to reduce a maximum size of gap present between (grounded) portions of the housing at the opening compared to when the cover is not provided, when the space corresponding to the opening is vacant.

The cover may be biased into a position in which the cover covers the one of the openings. The cover may be pivotally coupled to the one of the walls of the housing.

The cover may comprise a body and one or more electrically conductive elements arranged to extend over an area of the openings when the cover is covering the one of the openings. The one or more electrically conductive elements may be provided on a side, e.g. an inner side, of the cover that faces the one of the openings. The housing may further comprise a protecting element provided adjacent to the electrically conductive elements. The protecting elements may be arranged to contact the electrical component when the electrical is installed into the space covered by the cover.

The body may comprise a recessed area and a raised area. The electrically conductive elements may be received within the recessed area. A thickness of the electrically conductive elements may be less than a depth that the recessed area is recessed relative to the raised area. The raised area may extend in a first direction between an inside edge of the body, being the edge adjacent to a pivot axis about which the cover is to pivot relative to the housing, to an outside edge of the body opposite the inside edge.

The one or more electrically conductive elements may comprise a layer, e.g. a sheet, of an electromagnetic interference gasket material. In some example, the gasket material is relatively soft, to improve sealing of the cover against the housing.

The cover may comprise a handle provided at an opposite edge of the cover from at edge at which the cover is pivotally coupled to the one of the walls of the housing. The handle may be aligned with the raised area of the body in a direction perpendicular to the first direction. The handle may depend from the opposite edge along a length of the opposite edge between an end of the edge and a centre position along the edge, e.g. such that the handle is anti-symmetrically positioned along one lateral half the opposite edge.

The housing may comprise a plurality of covers each corresponding to a different one of the openings. The housing may comprise a cover corresponding to each of the spaces.

The housing may be a cage for Electromagnetic Interference (EMI) shielding of a Small Form-factor Pluggable (SFP) optical transceiver module.

According to another aspect of the present disclosure, there is provided a housing assembly. The housing assembly comprised a housing comprising a plurality of walls defining a plurality of spaces for receiving optical transceivers, e.g. pluggable optical transceivers. The housing defines a plurality of openings into the respective spaces. The housing comprises a cover movably coupled to one of the walls, the cover movable relative to the one of the walls in order to cover at least one of the openings, e.g. to reduce a maximum size of gap present between (grounded) portions of the housing compared to when the cover is not provided, at the opening when the space corresponding to the opening is vacant. The housing assembly further comprises a printed circuit board coupled to the housing such that electrical connectors provided on the printed circuit board are arranged to contact corresponding electrical connectors provided on optical transceivers installed within the spaces.

The housing may be a cage for Electromagnetic Interference (EMI) shielding of a Small Form-factor Pluggable (SFP) optical transceiver module.

The assembly may further comprise a further housing comprising a plurality of walls defining a plurality of spaces for receiving optical transceivers, e.g. pluggable optical transceivers. The further housing defines a plurality of openings into the respective spaces. The further housing comprises a cover movably coupled to one of the walls, the cover movable relative to the one of the walls in order to cover at least one of the openings, e.g. to reduce a maximum size of gap present between (grounded) portions of the further housing at the opening compared to when the cover is not provided, when the space corresponding to the opening is vacant, wherein the printed circuit board comprises further electrical connectors arranged to contact corresponding electrical connectors provided on optical transceivers installed within the spaces defined by the further housing.

To avoid unnecessary duplication of effort and repetition of text in the specification, certain features are described in relation to only one or several aspects or embodiments of the invention. However, it is to be understood that, where it is technically possible, features described in relation to any aspect or embodiment of the invention may also be used with any other aspect or embodiment of the invention.

### BRIEF DESCRIPTION OF THE DRAWINGS

For a better understanding of the present invention, and to show more clearly how it may be carried into effect, reference will now be made, by way of example, to the accompanying drawings, in which:

FIG. 1 is perspective view of a previously proposed housing for electrical components; and

FIG. 2 is a top cross-sectional view of the housing shown in FIG. 1;

FIG. 3 is a bottom view of an electrical component, e.g. a SFP optical transceiver, to be housed within the housing shown in FIGS. 1 and 2;

FIG. 4 is a top, cross-sectional view of the housing comprising a vacant space for receiving an electrical component;

FIG. 5 is a perspective view of a housing according to the present disclosure, with a cover in an open position;

FIG. 6 is a perspective view of the housing shown in FIG. 5, with the cover in a closed position;

FIG. 7 is a perspective, side view showing a cross section through the housing shown in FIGS. 5 and 6;

FIG. 8 is a side view of the housing shown in FIGS. 5 and 6, with an optical transceiver installed in a space associated with the cover;

FIG. 9 is a perspective rear view of a cover for the housing shown in FIGS. 5 to 8; and

FIG. 10 is a perspective view of a housing assembly according to the present disclosure.

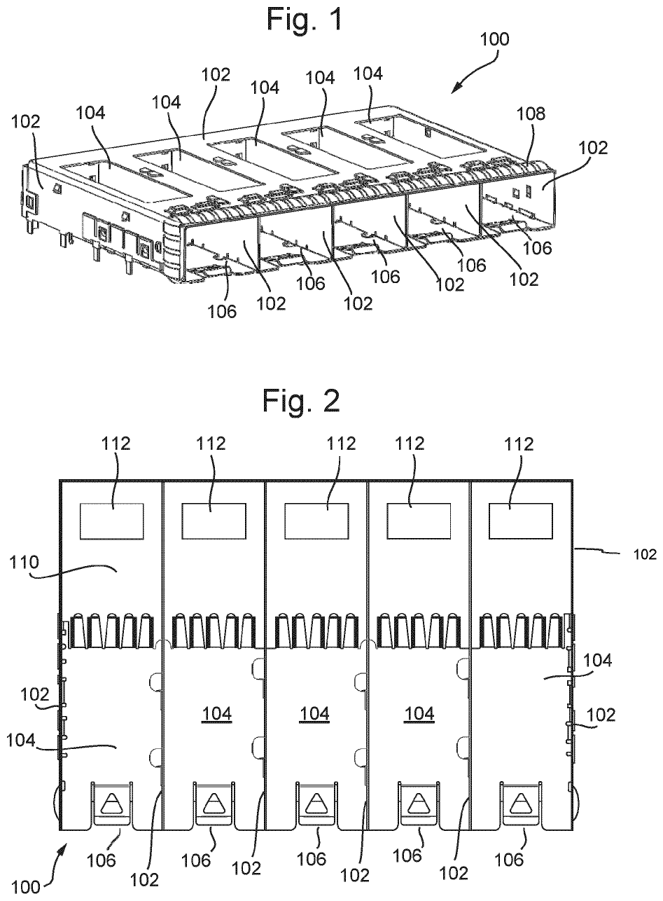

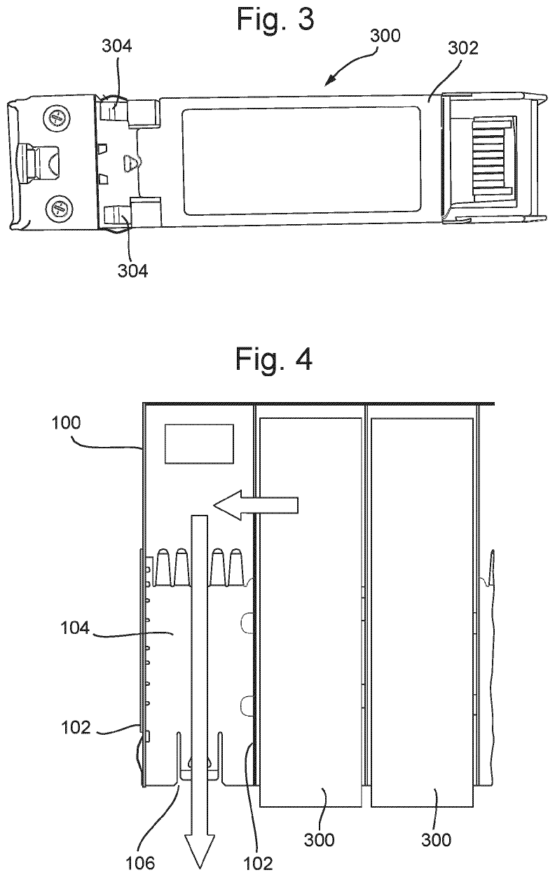

### DETAILED DESCRIPTION

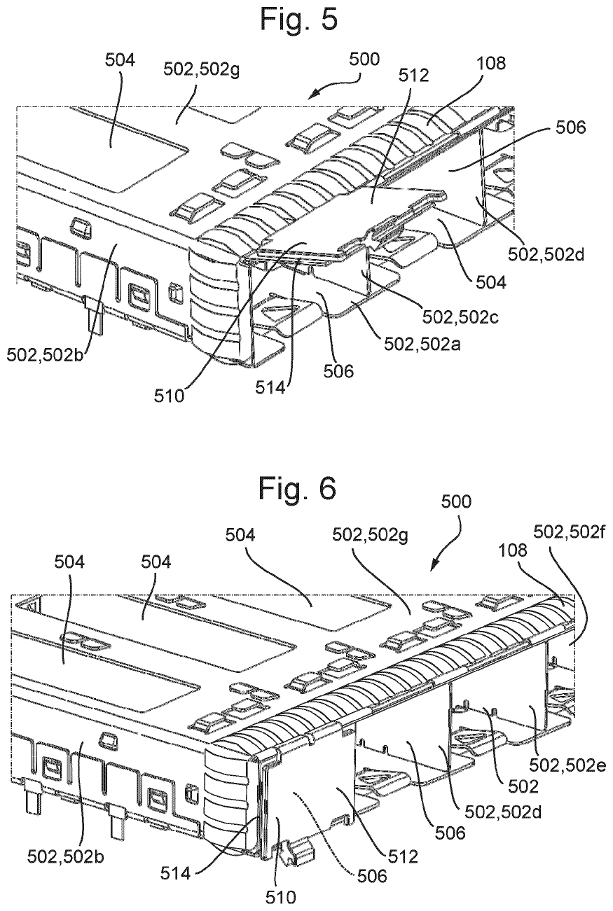

With reference to FIGS. 5 and 6, a housing 500 according to the present disclosure will now be described. The housing 500 is similar to the housing 100 described above and comprises a plurality of walls 502 defining a plurality of spaces 504 for receiving electrical components inside the housing 500. The spaces 504 may be for receiving optical transceivers, e.g. Small Form-factor Pluggable (SFP) optical transceivers. Accordingly, the spaces 504 may also be suitable for receiving plugs of Direct-Attached Copper (DAC) cable assemblies. In some arrangements, the spaces 504 may be suitable for receiving one or more other electrical components in addition to or as an alternative to the optical transceivers and/or DAC cable assembly plugs.

As depicted, the housing 500 may comprise a base wall 502a forming a bottom side of the spaces 504. The housing may further comprise three or more side walls 502b, 502c, 502d, 502e, 502f. The side walls 502b-502f may extend at an angle, e.g. perpendicular, to the base wall 502a and define lateral sides of the spaces 504. As depicted, the side walls 502b-502f are spaced apart across the base wall 502a and each of the spaces 504 is defined between an adjacent pair of the side walls 502b-502f. The housing may further comprise an upper wall 502g forming an upper side of the spaces 504.

The walls 502 of the housing may be manufactured from, or may comprise, an electrically conductive material. For example, the walls 502 may be manufactured from a sheet metal, such as sheet steel. Furthermore, the walls 502 may be electrically connected to one another. As described above, the housing 500 comprises a plurality of sprung fingers 108 for contacting the frame of the telecommunications unit in which the housing 500 is installed in order to establish a ground connection between the housing 500 and the frame of the telecommunications unit. The sprung fingers 108 may be electrically connected to the one or more of the walls 502, so that the walls 502 are electrically grounded.

The walls 502 further define openings 506 into the respective spaces 504. For example, edges of the walls 502 may form edges of the openings into the spaces defined by the walls. The openings 506 may be arranged, e.g. positioned and/or oriented, to enable the electrical components to be installed through into the spaces 504. Additionally or alternatively, the openings may be to enable one or more connections, such as optical and/or electrical, e.g. coaxial cables, to pass into the spaces to the electrical components installed within the housing.

As described above, the electrical components 300 may comprise electrical contacts 304 for contacting the walls 502 of the housing in order to establish a ground connection between the casing 302 of the electrical component 300 and the housing. Additionally, when the electrical component 300 is received within a particular space 504, the opening 506 into the particular spaces may be closed, e.g. substantially filled, by the casing 302 of the electrical component installed in the particular space. In this way, the electrical components 300 and the housing 500 may be configured to form an electrically grounded cage around the electrical components in order to prevent undesirable levels of electromagnetic interference, which may be generated by the electrical components, from being emitted from the housing.

In order to reduce the emission of electromagnetic interference through the openings e.g. into the vacant spaces, the housing 500 further comprises a cover 510. The cover 510 is configured, as described below, to cover one of the openings 506 when the space associated with that opening is vacant, e.g. does not contain an installed electrical component, in order to reduce the emission of electromagnetic interference from the housing 500, e.g. that has been generated by neighbouring electrical components housed in the other spaces of the housing, through the opening 506 into the vacant space.

In the arrangement shown in FIGS. 5 and 6, the housing 500 comprises a single cover 510 for covering a single one of the openings 506. However, in other arrangements, the housing 500 may comprise any number of covers configured to cover respective ones of the openings when the spaces associate with those openings are vacant. In some arrangements, the housing comprises a cover 510 associated within each of the openings 506.

When a particular opening is closed by a particular cover 510, the particular cover reduces a maximum size of gaps present between portions of the housing 500, e.g. grounded portions of the housing, at the particular opening. In other words, the cover may reduce a maximum distance between electrically grounded points on the housing 500 over the area of the opening. In other aspects, the cover may be considered as extending over substantially the whole area, or the whole area, or the opening. The cover comprises an electrically conductive material. The cover thereby improves electromagnetic interference shielding provided by the housing 500.

The cover 510 may be electrically connected to one or more of the walls of the housing, such that the cover 510 is electrically grounded. Additionally or alternatively, the cover 510 may be electrically grounded via one or more other ground connections. In one or more arrangements, the cover may electrically connect one or more points at an edge of the particular opening with one or more further points at the edge, or another edge, of the particular opening in order to reduce the maximum size of the gaps.

The cover 510 may comprise a body 512. In some arrangements, the body 512 may be manufactured from an electrically conductive material. The electrical connection(s) between the cover and the walls of the housing may be formed by the body 512. Additionally or alternatively, the cover 510 may further comprise one or more electrically conductive elements 514 coupled to the body 512 for forming the electrical connection(s). When the cover 510 comprises the one or more electrically conductive elements, the body may be manufactured from metal or an electrically conductive material such as conductive plastic.

The electrically conductive elements 514 may be arranged to over an area of the opening, when the cover is in the closed position covering the opening. The electrically conductive elements 514 may be arranged along and/or between one or more edges of the opening. The electrically conductive elements 514 may be provided on a surface, e.g. an inner surface, of the body 512 that faces the walls 502 of the housing when the cover is in the closed position. The electrically conductive elements 514 may comprise a layer or sheet over the body 512 of the cover, e.g. over the inner side of the body that faces the opening when the cover closes the opening. In some aspects, the electrically conductive elements 514 extends across an area of the housing opening. The cover provides for an electrically conductive area which extends across substantially the whole of the area of one of the housing openings.

The electrically conductive elements 514 may be configured to electrically connect the cover to the housing. For example, the electrically conductive elements may electrically connect to one or more discrete locations around the edge of the opening closed by the cover 510. For example, the electrically conductive elements 514 may form a grid or mesh extending over at least a portion of the opening, when the cover is in the closed position.

In other arrangements, the electrically conductive elements 514 may be configured to establish the electrically connection over a continuous length around the edge of the opening. In such arrangements, the electrically conductive elements 514 may comprise a sheet extending over the body, e.g. over the inner surface of the body facing the opening, such that the electrically conductive elements 514 covers at least a portion of the opening in a continuous manner when the cover is in the closed position. In some aspects, the electrically conductive elements 514 comprise a planar material. For example, in the arrangements shown in FIGS. 5 and 6, the electrically conductive elements 514 comprise a sheet of electromagnetic interference gasket material.

The cover 510 is movably coupled, e.g. attached, to the walls 502 of the housing. For example, the cover 510 may be movable, e.g. pivotally or rotatably, coupled to the upper wall 502g of the housing. In particular, the cover 510 may be pivotally coupled to a portion of the upper wall of the housing forming the opening 506 that the cover 510 is associated with.

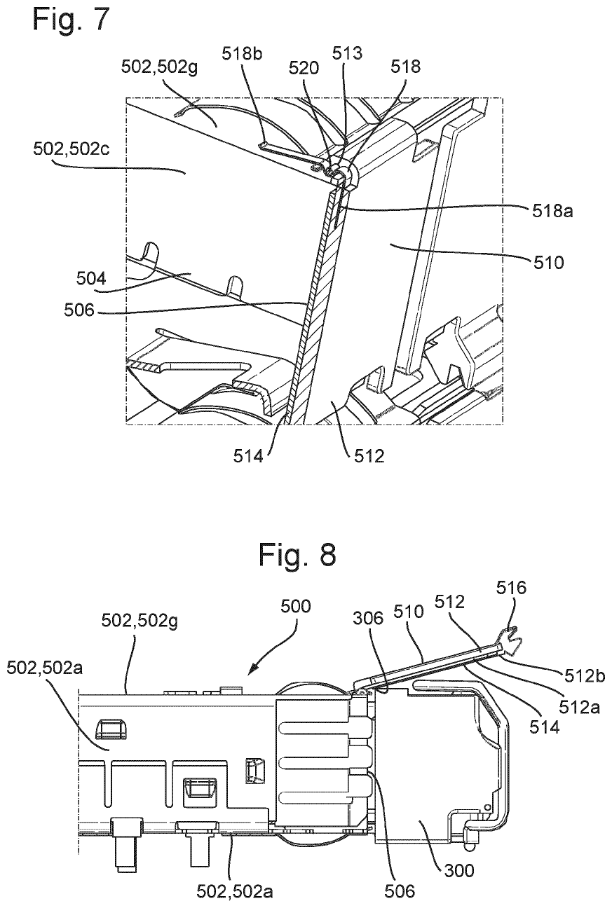

With reference to FIG. 7, the body 512 of the cover may comprise an aperture 513 for receiving a pivot pin 520 about which the body 512 can pivot relative to the walls 502 of the housing. As depicted in FIG. 7, the pivot pin 520 may be coupled to one of the walls of the housing along an edge of the opening defined by the wall. As described above, the wall may be manufactured from a sheet metal material and the pivot pin 520 may be coupled to the wall by bending or rolling the sheet metal material around the pivot pin 520 at the edge of the opening. Alternatively, the pivot pin may be coupled to the wall of the housing along the edge of the opening using any other suitable method.

The cover 510 may be movable between an open position, depicted in FIG. 5, in which the opening 506 associated with the cover is not closed by the cover; and a closed position, depicted in FIG. 6, in which the opening associated with the cover is closed, e.g. covered, by the cover.

The cover 510 may be mechanically biased into the closed position. As shown in FIG. 7, the cover 510 may comprise a resilient element 518 arranged so as to be resiliently deformed when the cover 510 is moved from the closed position to the open position and to then act against one or more of the walls of the housing, such as the upper wall 502g, to bias the cover 510 into the closed position. The resilient element 518 may comprise a torsional spring arranged to act between the cover 510 and the wall 502g of the housing in order to bias the cover into the closed position. As depicted in FIG. 7, a first end 518a of the resilient element 518 may be coupled in the body 512 and the resilient element 518 may be arranged such a second end 518b of the resilient element is forced against one of the walls of the housing as the cover is moved from the closed position to the open position, to thereby resilient deform the resilient element. The resilient element 518 may extend from the body 512 between the pivot pin 520 and a wall of the housing.

As shown in FIG. 7, the first end 518a of the resilient element 518 may be received in an opening formed in the body 512 and may be coupled to the body at the opening. For example, the resilient element 518 may be adhered to the body at the bore. Alternatively, the body 512 may be over-moulded around the resilient element 518, e.g. using an injection moulding process. Alternatively again, the resilient element 518 may be coupled to the body using any other desirable process.

As shown in FIG. 8, when an electrical component, such as an SFP optical transceiver 300, is installed within the space associated with the cover 510, the presence of the electrical component may prevent the cover 510 from being in the closed position. However, when the electrical component 300 is removed from the space associated with the cover, the cover may move to the closed position by virtue of its mechanical bias.

Additionally, as shown in FIG. 8, when the electrical component 300 is installed within the space associated with the cover 510, an edge 306 of the electrical component 300 may be in contact with a side of the cover 510 that faces the opening when the cover is in the closed position. Furthermore, when the electrical component is removed from the space, the edge 306 of the electrical contact may maintain contact with the side of the cover due to the cover being biased towards the closed position. In other words, as the electrical component is removed, the edge of the electrical component may rub or scrape along the side of the cover that faces the opening 506 when the cover is closed. As described above, the electrically conductive elements 514, such as the electromagnetic interference gasket material may be provided on the surface at the side of the cover 510 that faces the opening. Contact between the electrical component 300 and the side of the cover 510 may risk damage the electrically conductive elements 514 and degradation of the electromagnetic interference shielding performance of the cover 510.

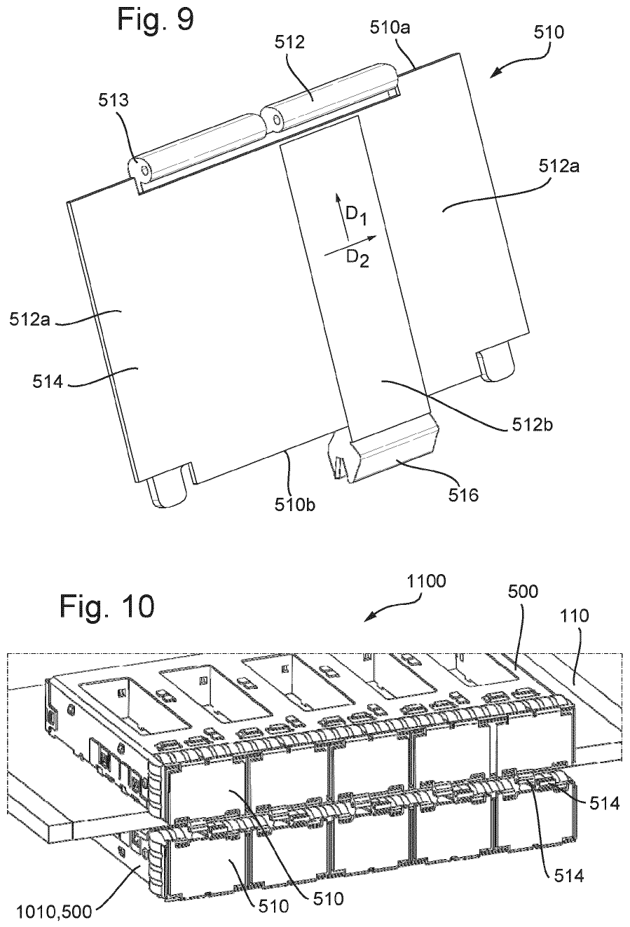

With reference to FIGS. 8 and 9, in order to reduce the risk of damage to the electrically conductive elements 514, a first area 512a of the side of the body 512 facing the opening may be recessed relative to a second area 512b of the side of the body facing the opening. As illustrated in FIG. 9, the electrically conductive elements 514, e.g. the electromagnetic gasket material, may be provided over the side of the body facing the opening in the first area 512a. The second area 512b may be free from electrically conductive elements 514. A thickness of the electrically conductive elements 514 may be less than a different in thickness of the body 512 between the first and second areas 512a, 512b. Hence, the electrically conductive elements 514 may not protrude from the body portion beyond the surface of the body portion facing the opening in the second area 512b. In this way, the edge 306 of the electrical component may contact the body portion in the second area 512b, rather than contacting the electrically conductive elements 514.

As illustrated, the second area 512b may extend over the side of the body portion in a first direction D₁ from or close to an inside edge 510a of the cover 510 adjacent to the pivot pin 520 to an outside edge 510b of the cover opposite from the pivot pin 520. The second area 512b may have a width in a second direction D₂ perpendicular to the first direction D₁ that is less than a width of the opening 506 into the housing space, so that the second area 512b of the body portion does not prevent the electrically conductive elements 514 contacting the edges of the opening across the full width of the opening. Furthermore, as depicted, the second area 512b may not extend the complete length of the side between the inside edge 510a and the outside edge 510b so that the first area can extend across the complete width of the side of the cover in the second direction.

In other arrangements, a protective layer may be provided over the electrically conductive elements 514, e.g. such that the electrically conductive elements are provided between the body and the protective layer. The protective layer may thereby be arranged to be contacted by the edge 306 of the electrical component, rather than the electrically conductive elements 314. The protective layer may extend over the electrically conductive elements in the first direction D₁ from or close to the inside edge 510a of the cover adjacent to the pivot pin 520 to the outside edge 510b of the cover opposite from the pivot pin. The protective layer 517 may have a width in the second direction D₂ perpendicular to the first direction that is less that the width of the opening, so that the protective layer 517 does not prevent the electrically conductive elements contacting the edges of the opening.

The cover 510 may further comprise a handle 516 to be gripped by a user in order to move the cover 510 between the closed position and the open position, e.g. in order to move the cover into the open position depicted in FIG. 5, so that an electrical component can be installed through the opening 506 into the space 504 associated with the cover. As depicted in FIG. 9, the handle 516 may depend from the outside edge 510b of the cover. The handle may be coupled to, e.g. attached to or integrally formed with, the body portion. The handle 516 may be arranged to one (lateral) side of the cover, e.g. in the second direction D₂. In other words, the handle 516 may depend from the outside edge 510b on one lateral side of a centre point along the outside edge. In other words, the handle 516 is off-center on the edge of the cover. This may enable two of the housings 500 to be arranged “belly-to-belly”, as described below with reference to FIG. 10, without the handles 516 of the covers on opposing housings clashing.

As shown in FIG. 9, the handle 516 may be aligned with the second area 512b of the body portion in the second direction D₂. In this way, the increased thickness of the body portion in the second area may act to improve the stiffness of the cover between the handle 516 and the pivot pin 520, whilst also acting to protect the electrically conductive elements 514 from contact with the electrical component 300, as described above. In some aspects, the second area 512b is formed of, or comprises a layer of, electrically conductive material. The material, e.g. a plastic or metal, is raised above the electrically conductive elements 514 in one or more first areas 512a. As such, when the cover contacts an insertable component 300, the cover contacts the component 300 only on the second area 512b. This protects the material of the first areas 512a (electrically conductive elements 514) from damage from contacting the component 300.

With reference to FIG. 10, a housing assembly 1100 according to the present disclosure comprises the housing 500 and a Printed Circuit Board (PCB) 110 coupled to the housing such that electrical connectors provided on the printed circuit board are arranged to contact corresponding electrical connectors provided on electrical component, such as SFP optical transceivers and/or DAC cable assembly plugs, installed within the spaces defined by the housing. For example, the housing 500 may be coupled to the PCB 110 in the same way as the housing 100 depicted in FIG. 2.

The housing assembly 1100 may comprise a further housing 1010, which may be the same as the housing 500. The further housing 1010 may be coupled to an opposite side of the PCB from the housing assembly 1100. As depicted, the further housing 1010 may be arranged in an orientation which mirrors the orientation of the housing 500 in the plane of the PCB 110. In other words, the housing and further housing may be arranged “belly to belly”. As described above, due to the handles 516 of the covers 510 being provided along one lateral half of the outside edges 510b of the covers, the handles 516 on the covers of the housings my not clash with the handles on the covers of the further housing 1010 and space may be provided for an installer to grip the handles 516 to open the covers in order to install electrical components 300 into the spaces defined by the housing and the further housing.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

It will be appreciated by those skilled in the art that although the invention has been described by way of example, with reference to one or more exemplary examples, it is not limited to the disclosed examples and that alternative examples could be constructed without departing from the scope of the invention as defined by the appended claims.

1.-17. (canceled)

18. A housing for optical transceivers, the housing comprising:
a plurality of walls arranged to define a plurality of spaces for receiving the optical transceivers, with a plurality of openings into the respective spaces; and
a cover movably coupled to a first one of the walls, with the cover being movable relative to the first wall to cover to cover at least one of the openings, when the at least one space corresponding to the at least one opening is vacant.

19. The housing of claim 18, wherein the cover is mechanically biased into a position such that the cover covers the at least one of the openings.

20. The housing of claim 18, wherein the cover is pivotally coupled to the first wall of the housing.

21. The housing of claim 18, wherein:
the cover comprises a body and one or more electrically conductive elements; and
when the cover is arranged to cover the at least one of the openings, the one or more electrically conductive elements extend over an area of the openings.

22. The housing of claim 21, wherein:
the one or more electrically conductive elements are provided on a side of the cover that faces the at least one of the openings;
the housing further comprises a protecting element arranged adjacent to the one or more electrically conductive elements; and
the protecting element is arranged to contact an optical transceiver when the optical transceiver is installed into a space covered by the cover.

23. The housing of claim 21, wherein:
the body of the cover comprises a recessed area and a raised area;
the one or more electrically conductive elements of the cover are arranged within the recessed area; and
a thickness of the one or more electrically conductive elements is less than a depth that the recessed area is recessed relative to the raised area.

24. The housing of claim 23, wherein:
the raised area extends in a first direction between an inside edge of the body to an outside edge of the body opposite the inside edge; and
the inside edge is adjacent to a pivot axis about which the cover is to pivot relative to the housing.

25. The housing of claim 21, wherein the one or more electrically conductive elements comprise a layer of an electromagnetic interference gasket material.

26. The housing of claim 18, wherein:
a first edge of the cover is movably coupled to the first wall of the housing; and
the cover comprises a handle positioned at a second edge of the cover opposite the first edge.

27. The housing of claim 26, wherein the handle is aligned with the raised area of the body in a direction perpendicular to the first direction.

28. The housing of claim 26, wherein the handle is positioned along a length of the second edge between an end of the edge and a center position along the edge.

29. The housing of claim 18, wherein the housing comprises a plurality of covers each corresponding to a different one of the openings.

30. The housing of claim 29, wherein the plurality of covers correspond respectively to the plurality of spaces.

31. The housing of claim 18, wherein the housing is a cage for electromagnetic interference shielding of small form-factor pluggable optical transceiver modules installed within the spaces.

32. A housing assembly comprising:
a first housing for optical transceivers, the first housing comprising:
a first plurality of walls arranged to define a first plurality of spaces for receiving the optical transceivers, with a first plurality of openings into the respective spaces; and
a cover movably coupled to a first one of the first plurality of walls, with the cover being movable relative to the first wall to cover to cover at least one of the first plurality of openings, when the at least one space corresponding to the at least one opening is vacant; and
a printed circuit board coupled to the first housing such that electrical connectors provided on the printed circuit board are arranged to contact corresponding electrical connectors provided on optical transceivers installed within the spaces defined by the first housing.

33. The housing assembly of claim 32, wherein the housing is a cage for electromagnetic interference shielding of small form-factor pluggable optical transceiver modules inserted into the spaces.

34. The housing assembly of claim 32, further comprising
a second housing for optical transceivers, the second housing comprising:
a second plurality of walls arranged to define a second plurality of spaces for receiving the optical transceivers, with a second plurality of openings into the respective spaces; and
a cover movably coupled to a first one of the second plurality of walls, with the cover being movable relative to the first wall to cover to cover at least one of the second plurality of openings, when the at least one space corresponding to the at least one opening is vacant,
wherein the printed circuit board comprises further electrical connectors arranged to contact corresponding electrical connectors provided on optical transceivers installed within the spaces defined by the second housing.
